(19) United States
(12) Patent Application Publication
(10) Pub. No.: US 2023/0028662 A1
(43) Pub. Date: Jan. 26, 2023

(54) SYSTEM AND METHOD FOR ADJUSTING GAS PATH FLOW OF APPARATUS

(71) Applicant: CHANGXIN MEMORY TECHNOLOGIES, INC., Hefei, Anhui (CN)

(72) Inventor: Hailong ZHANG, Hefei (CN)

(73) Assignee: CHANGXIN MEMORY TECHNOLOGIES, INC., Hefei, Anhui (CN)

(21) Appl. No.: 17/609,467

(22) PCT Filed: Mar. 8, 2021
(86) PCT No.: PCT/CN2021/079599

§ 371 Date: Nov. 8, 2021

(30) Foreign Application Priority Data
Apr. 14, 2020 (CN) 202010290176.0

(51) Int. Cl. G05D 7/06

(52) U.S. Cl. CPC G05D 7/0623; G05D 7/0635; H01L 22/20

(57) ABSTRACT

A system for adjusting a gas path flow of an apparatus includes: a process task prediction component of the apparatus, a gas path flow monitoring component, and a gas path flow control component; wherein the process task prediction component of the apparatus predicts a process schedule of the apparatus, the gas path flow monitoring component is configured to monitor a gas path flow of the apparatus in real time, when the gas path flow exceeds the preset range of flow, the gas path flow control component judges a current process status of the apparatus based on the process schedule, and issues a corresponding flow control instruction

### CROSS-REFERENCE TO RELATED APPLICATIONS

The present disclosure claims priority to Chinese Patent Application No. 202010290176.0, entitled “SYSTEM AND METHOD FOR ADJUSTING GAS PATH FLOW OF APPARATUS” and filed on 14 April, 2020, the entire contents of which are incorporated herein by reference.

### TECHNICAL FILED

The present disclosure relates to the field of semiconductor measurement equipment technologies, in particular to a system and method for adjusting a gas path flow of an apparatus.

### BACKGROUND

A stage of photolithography process is of paramount importance among individual stages of a semiconductor manufacturing process. An objective of the photolithography process is to form a patterned Photo Resist (PR), and then use the patterned photo resist as a mask to etch exposed portions of a material layer, so as to pattern the material layer. The patterned material layer has a Critical Dimension (CD). A change in the critical dimension has a great influence on characteristics of electronic elements. In order to guarantee qualities of the electronic elements, the critical dimension is required to be measured after the photolithography process.

During a measurement of the critical dimension, a to-be-measured wafer is required to be placed in a CD measurement apparatus. In order to ensure an accuracy of the CD measurement and prevent other impurities from exerting an error effect on a measurement result, a gas path system is required to be provided to the CD measurement apparatus to remove impurities and guarantee a stable measurement environment of the CD measurement apparatus. It should be noted that, in order to guarantee a stable intra-cavity pressure of the CD measurement apparatus and a good measurement accuracy, a magnitude of a gas path flow should be limited to within a certain range.

However, in a related art, an adjustment of the gas path flow is prone to a reduced production efficiency and is required to be regulated repeatedly by a labor, an operation of which is complicated and lays a burden on manpower.

### SUMMARY

According to embodiments of the present disclosure, a system and method for adjusting a gas path flow of an apparatus is provided to solve problems that a related gas path flow adjustment scheme causes delay of process progress and has complicated operations.

In an aspect of the present disclosure, a system for adjusting a gas path flow of an apparatus according to embodiments of the present disclosure is provided, the system including:

a process task prediction component of the apparatus, a gas path flow monitoring component, and a gas path flow control component;

wherein the process task prediction component of the apparatus is configured to collect production line information and predict a process schedule of the apparatus based on the production line information;

the gas path flow monitoring component is configured to monitor a gas path flow of the apparatus in real time; and

the gas path flow control component is communicably connected to both the process task prediction component of the apparatus and the gas path flow monitoring component, and the gas path flow control component is configured to judge whether the gas path flow exceeds a preset range of flow; when the gas path flow exceeds the preset range of flow, the gas path flow control component judges a current process status of the apparatus based on the process schedule provided by the process task prediction component of the apparatus, and issues a corresponding flow control instruction based on the process status.

In another aspect of the present disclosure, a method for adjusting a gas path flow of an apparatus according to embodiments of the present disclosure is further provided, the method including:

collecting, by a process task prediction component of the apparatus, production line information and predicting, by the process task prediction component of the apparatus, a process schedule of the apparatus based on the production line information;

monitoring, by a gas path flow monitoring component in real time, a gas path flow of the apparatus; and

judging, by a gas path flow control component, whether the gas path flow exceeds a preset range of flow, and when the gas path flow exceeds the preset range of flow, judging, by the gas path flow control component, a current process status of the apparatus based on the process schedule provided by the process task prediction component of the apparatus, and issuing, by the gas path flow control component, a corresponding flow control instruction based on the process status.

In the present disclosure, the system for adjusting a gas path flow of an apparatus includes a process task prediction component of the apparatus, a gas path flow monitoring component, and a gas path flow control component, so as to realize an automatic adjustment of a gas path flow of an apparatus. Specifically, the process task prediction component of the apparatus predicts a process schedule of the apparatus based on collected production line information; the gas path flow monitoring component is capable of monitoring a gas path flow of the apparatus in real time; the gas path flow control component has a preset range of flow, and when the gas path flow exceeds the preset range of flow, the gas path flow control component can judge a current process status of the apparatus based on the process schedule, namely judging whether the apparatus is currently in a process trip, and issue a corresponding flow control instruction based on the process status, such that the gas path flow is adjusted to be within the preset range of flow by the gas path flow control component besides the process trip. Therefore, the gas path flow is automatically adjusted without affecting a normal process progress. The adjustment procedure is simple, and there is no need to repeatedly step down from the apparatus to adjust the gas path flow, reducing manpower burden. The procedure of adjusting the gas path flow according to the embodiments of the present disclosure would not delay each process trip, and instead, improves a working efficiency of measurement of the apparatus and accelerates product manufacturing progress.

### BRIEF DESCRIPTION OF THE DRAWINGS

The aforementioned and other features and advantages of the present invention will become more obvious through detailed description of example embodiments with reference to the accompanying drawings.

FIG. 1 is a schematic structural diagram of a system for adjusting a gas path flow of an apparatus according to an embodiment of the present disclosure;

FIG. 2 is a schematic structural diagram of a system for adjusting a gas path flow of an apparatus according to another embodiment of the present disclosure;

FIG. 3 is a schematic flowchart of a method for adjusting a gas path flow of an apparatus according to an embodiment of the present disclosure;

FIG. 4 is a schematic flowchart of another method for adjusting a gas path flow of an apparatus according to an embodiment of the present disclosure; and

FIG. 5 is a schematic flowchart of yet another method for adjusting a gas path flow of an apparatus according to an embodiment of the present disclosure.

### DETAILED DESCRIPTION

Detailed descriptions of the present disclosure are further given below in combination with the accompanying drawings and embodiments. It can be understood that particular embodiments described herein are merely used for explaining, but not limiting, the present disclosure. It should be further noted that, for convenience of description, rather than an entire structure, only parts that are related to the present disclosure are illustrated in the accompanying drawings.

In a related art, in the case of adjusting a gas path flow, a CD measurement apparatus is required to be suspended after a pressure value of the apparatus exceeds a reference range, and an adjusting screw of a regulating valve is rotated left or right to increase or decrease the pressure, so as to adjust the pressure value to within a permissible range. Such an operation of suspending the apparatus adds a latency to entire process progress and affects regular production efficiency. Besides, after the apparatus is suspended, a labor is required to repeatedly make adjustments until a labeled range is reached. Such operations are complicated and lay a burden on manpower; repeated operations are required for an adjustment to a specific value. In addition, due to vibration of the apparatus, clamp nuts likely become loose, which also causes fluctuation of the gas path flow.

According to embodiments of the present disclosure, a system for adjusting a gas path flow of an apparatus is provided, including: a process task prediction component of the apparatus, a gas path flow monitoring component, and a gas path flow control component.

The process task prediction component of the apparatus is configured to collect production line information and predict a process schedule of the apparatus based on the production line information.

The gas path flow monitoring component is configured to monitor a gas path flow of the apparatus in real time.

The gas path flow control component is communicably connected to both the process task prediction component of the apparatus and the gas path flow monitoring component, and the gas path flow control component is configured to judge whether the gas path flow exceeds a preset range of flow; when the gas path flow exceeds the preset range of flow, the gas path flow control component judges a current process status of the apparatus based on the process schedule provided by the process task prediction component of the apparatus, and issues a corresponding flow control instruction based on the process status.

In embodiments of the present disclosure, a system for adjusting a gas path flow of an apparatus includes a process task prediction component of the apparatus, a gas path flow monitoring component, and a gas path flow control component, to realize an automatic adjustment of a gas path flow of an apparatus. Specifically, the process task prediction component of the apparatus predicts a process schedule of the apparatus based on collected production line information; the gas path flow monitoring component is capable of monitoring a gas path flow of the apparatus in real time; the gas path flow control component has a preset range of flow, and when the gas path flow exceeds the preset range of flow, the gas path flow control component can judge a current process status of the apparatus based on the process schedule, namely judging whether the apparatus is currently in a process trip, and issue a corresponding flow control instruction based on the process status, such that the gas path flow is adjusted to be within the preset range of flow by the gas path flow control component besides the process trip. Therefore, the gas path flow is automatically adjusted without affecting a normal process progress. The adjustment procedure is simple, and there is no need to repeatedly step down from the apparatus to adjust the gas path flow, reducing manpower burden. The procedure of adjusting the gas path flow according to the embodiments of the present disclosure would not delay each process trip, and instead, improves a working efficiency of measurement of the apparatus and accelerates product manufacturing progress.

The contents above are core ideas of the present disclosure. Technical solutions of embodiments of the present disclosure are described clearly and thoroughly below in combination with drawings corresponding to the embodiments of the present disclosure. All of further embodiments obtained by ordinary skills in the art based on the embodiments of the present disclosure without paying any creative labor fall within the protection scope of the present disclosure.

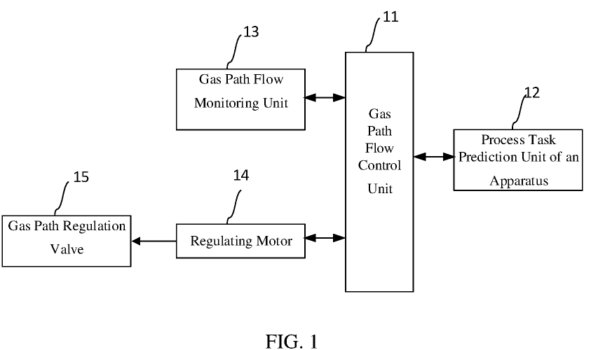

FIG. 1 is a schematic structural diagram of a system for adjusting a gas path flow of an apparatus is provided according to an embodiment of the present disclosure. As shown in FIG. 1, the system for adjusting a gas path flow of an apparatus includes a process task prediction component of the apparatus 12, a gas path flow monitoring component 13, and a gas path flow control component 11.

The gas path flow monitoring component 13 may be disposed in a cavity of the apparatus and is configured to measure a gas path flow. The gas path flow monitoring component 13 is also capable of sending the gas path flow to the gas path flow control component 11, such that the gas path flow control component 11 can monitor the gas path flow. For example, the gas path flow monitoring component 13 may be a pressure sensor. The gas path flow is acquired based on a pressure within the cavity. A gas path flow range which is determined from a critical dimension monitoring effect is saved on the gas path flow control component 11. In the embodiment, the range is a preset range of flow. When the gas path flow is in the preset range of flow, the apparatus is considered to be in a normal range of flow.

The process task prediction component of the apparatus 13 can collect production line information, and based on the production line information, predict a process condition for a certain time period. Alternatively, a process condition may be input into the process task prediction component of the apparatus 13, i.e., the process task prediction component of the apparatus 13 can acquire a process schedule of the apparatus which records process trip time of each process trip for a time period in the future. For example, the process task prediction component of the apparatus 13 keeps a record of the process trip time of each process trip for the next 24 hours or 48 hours. For example, Table 1 is a process schedule according to an embodiment of the present disclosure, which shows process numbers of process trips and process trip time in one-to-one correspondence to the process numbers. A time interval exists between two sequential process trips.

Table 1

a process schedule according to an embodiment of the present disclosure

| Process trip | Process trip time | |
|---|---|---|
| 101 | 2019-10-29 | 11:24:30 |
| 102 | 2019-10-29 | 11:26:33 AM |
| 103 | 2019-10-29 | 11:28:48 AM |
| 104 | 2019-10-29 | 11:53:38 AM |
| 105 | 2019-10-29 | 12:13:15 PM |
| 106 | 2019-10-29 | 12:36:39 PM |

The gas path flow control component 11 may compare, in real time, the measured gas path flow and a boundary of the preset range of flow. When the measured gas path flow is not in the preset range of flow, the gas path flow control component 11 judges a process status of the apparatus based on the process schedule above, and issues a corresponding flow control instruction based on the process status, thereby adjusting the gas path flow to be within the preset range of flow.

In the embodiment, the gas path flow can be adjusted in a first time period between normal process trips, such that individual process trips will not have delays, which avoids affecting the normal process trips of the apparatus.

In an embodiment, the system for adjusting the gas path flow of the apparatus may further include a regulating motor 14 and a regulating valve 15 mechanically connected to the regulating motor 14. The regulating motor 14 may rotate under control of the gas path flow control component 11, thereby driving a rotation of the regulating valve 15 of the gas path, so as to regulate the gas path flow.

In an embodiment, the process that the gas path flow control component 11 judges a current process status of the apparatus based on the process schedule provided by the process task prediction component of the apparatus 12 and issues a corresponding flow control instruction based on the process status may specifically include: when the gas path flow exceeds the preset range of flow, calculating, by the gas path flow control component 11, a time interval between a current time and a next process time based on the process schedule, and judging, by the gas path flow control component 11, whether the apparatus is currently in an idle condition or an in-process condition; if the apparatus is in an idle condition and the time interval is no less than a preset duration, controlling the gas path flow; if the apparatus is in the in-process condition and the time interval is no less than the preset duration, controlling the gas path flow when this process trip ends; if the time interval is less than the preset duration, performing no gas path flow control this time and the apparatus continuing to operate based on the process schedule; when a next process trip is finished, the gas path flow control component 11 repeats the process above until the time interval is no less than the preset duration, and then controls the gas path flow.

When the gas path flow exceeds the preset range of flow, the gas path flow control component 11 first calculates the time interval between the current time and the next process time based on the process schedule, and acquires the current process status of the apparatus. In the embodiment, the process status includes: idle condition and in-process condition. If the apparatus is currently in the idle condition and the time interval to the next process time is no less than the preset duration, the gas path flow control component 11 controls the gas path flow. If the apparatus is currently in the in-process condition, the gas path flow is adjusted when this process trip ends.

If the gas path flow exceeds the preset range of flow and the time interval between the current time and the next process time is less than the preset duration, the gas path flow is not adjusted regardless of whether the apparatus is in the idle condition or the in-process condition, such that the apparatus continues to operate based on the process schedule, and the gas path flow control component 11 may repeat checking the time interval between the current time and the next process time until the time interval is no less than the preset duration, and then control the gas path flow for that time interval.

In the embodiment, the gas path flow is adjusted in a first time period between two sequential process trips, such that individual process trips are guaranteed to be carried out based on the process schedule and prevented from delays. It is effectively realized that the gas path flow may be adjusted at any time, and neither an appointment of stepping down from the apparatus nor stopping or disturbing a process progress of the apparatus is required, improving a working efficiency of detection of the apparatus.

In an embodiment, the preset duration at least includes a flow regulating duration and an apparatus stabilizing duration. The preset duration above reserves the duration of regulating the gas path flow by the gas path flow control component 11, such that sufficient time is supplied to the process of regulating each gas flow, avoiding an inaccurate adjustment caused by an insufficient time. It also reserves the duration of apparatus stabilization when the adjustment is finished, such that the apparatus can be in a steady state to carry out a next process trip, improving a measurement accuracy of the apparatus.

In an embodiment, the preset duration may be greater than or equal to 15 min. In the embodiment, in order to guarantee a successful adjustment of gas path flow, the time interval cannot be selected as an excessively short time. In the embodiment, a time interval with a duration greater than or equal to 15 min is selected. Referring to FIG. 1 continuously, it can be seen that the process trip time for the process trip 103 is 11:28:48, the process trip time for the process trip 104 is 11:53:38, and a first time period between the two process trips is 25 min. The duration of the first time period is greater than 15 min, i.e. the duration of adjusting the gas path flow in the first time period is greater than 15 min. As such, remaining time is guaranteed after the adjustment of gas path flow. Therefore, a next process trip may not be performed until the stabilization of the apparatus, offering the required time of adjusting the gas path flow of the apparatus. However, in the embodiment, a time interval with a duration greater than the preset duration does not always exist, and all of the time intervals possibly have durations less than 15 min. At this point, the gas path flow control component 11 and the process task prediction component of the apparatus 13 may keep communicating, until the gas path flow control component 11 detects a time interval with a duration greater than the preset duration, and then adjusts the gas path flow of the apparatus.

In the present embodiment, there may be a plurality of the first time periods above. A first time period with a maximum duration may be screened out among the first time periods, so as to adjust the gas path flow. This can not only fulfill the adjustment task, but also avoid delaying subsequent process trips, avoiding accumulation of goods in the apparatus.

The preset range of flow may be 57 L/min to 63 L/min. In the present embodiment, the preset range of flow may be set as 57 L/min to 63 L/min to achieve the measurement accuracy of the apparatus.

In an embodiment, the gas path flow control component 11 is further configured to set a preset monitoring interval based on the preset range of flow. The preset monitoring interval is located within and less than the preset range of flow. The gas path flow control component 11 is further configured to judge the current process status of the apparatus when the gas path flow exceeds the preset monitoring interval, and issues the corresponding flow control instruction based on the process status.

In an embodiment, a preset monitoring interval may be further set based on the preset range of flow. A difference value exists between the preset monitoring interval and the preset range of flow. In the embodiment, the preset monitoring interval may be set to be within and less than the preset range of flow. When the gas path flow control component 11 detects that the gas path flow exceeds the preset monitoring interval, the gas path flow is adjusted based on the process status, thereby achieving a warning effect in advance, so as to improve the measurement accuracy of the apparatus. For example, if the preset range of flow is 57 L/min to 63 L/min, the preset monitoring interval may be set as 59 L/min to 61 L/min. In the embodiment, the preset monitoring interval is not specifically limited. Further, a median of the preset monitoring interval may be the same as a median N of the preset range of flow; the preset monitoring interval is (N-0.5) to (N+0.5) L/min. In the embodiment, in order to further limit the gas path flow to a numerical range in which a good measurement effect is realized, i.e., close to the median N of the preset range of flow. The median N is an ideal value for the gas path flow, and a small interval (N-0.5) to (N+0.5) L/min approximate to the median N is set as a median interval to further improve the measurement accuracy of the apparatus. For example, if the preset range of flow is 57 L/min to 63 L/mni, the median N is 60 L/min, and the gas path flow may be adjusted to the median interval of 59.5 to 60.5 L/min in the embodiment.

Even if the gas path flow of the apparatus falls within the preset range of flow, in the case where the gas path flow of the apparatus is a boundary value for a long time, the measurement accuracy of the apparatus may also be affected. The gas path flow control component 11 can limit the gas path flow to be within the preset monitoring interval, which prevents the gas path flow from approaching the boundary values of the preset range of flow, so as to guarantee a stable environment of measuring the critical dimension and improve the measurement accuracy of the apparatus. In the embodiment, the gas path flow is adjusted immediately when approaching the boundary values, which avoids omitting a warning from the apparatus and thus, avoids downtime of the apparatus, reducing adjustment time and downtime of the apparatus.

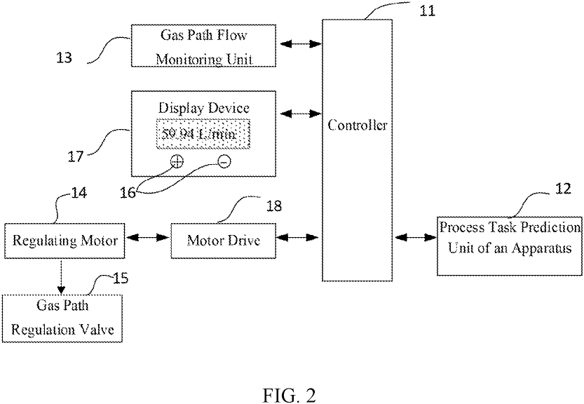

FIG. 2 is a schematic structural diagram of a system for adjusting a gas path flow of an apparatus according to an embodiment of the present disclosure. As shown in FIG. 2, a regulating motor 14 may be a servo motor, and the system for adjusting a gas path flow of an apparatus may further include a motor driver 18. The gas path flow control component 11 controls movement of the regulating motor 14 through the motor driver 18.

The servo motor may control a rotary component of a mechanical element, and has a controlled speed and a high position accuracy. The servo motor may convert a voltage signal to a torque and a rotate speed, so as to drive the gas path regulating valve 15. A rotor speed of the servo motor is controlled by an input signal, and can respond quickly. In an automatic control system, the servo motor serves as an actuation element, and can convert the received electrical signal to an angular displacement and an angular speed output to a motor shaft. It should be noted that, no autorotation phenomenon exists when the signal voltage is zero, and after the adjustment, the regulating valve is in a dead lock state and will not become loose, which guarantees the regulating accuracy of the gas path regulating valve 15 and thus, guarantees the regulating accuracy of the gas path flow. The servo motor can achieve a positioning accuracy of 0.001 mm, and has a positioning advantage superior to other motors.

Referring to FIG. 2continuously, the system for adjusting the gas path flow of the apparatus may further include a display device 17. The display device 17 is communicably connected to the gas path flow monitoring component 13 and is configured to display the gas path flow of the apparatus in real time. The display device 17 is electrically connected to the gas path flow control component 11 and is configured to display the gas path flow in real time, which facilitates a user to see the gas path flow value in time and thus, control the gas path flow of the apparatus.

As shown in FIG. 2, the system for adjusting the gas path flow of the apparatus may further include a manual adjustment device 16. The manual adjustment device 16 is configured to receive a set gas path flow entered by a user, so as to cause the gas path flow monitoring component 11 to issue a corresponding flow control instruction based on the set gas path flow and the process status. The manual adjustment device 16 may be integrated to the display device 17, and the implementation thereof is realized through a touch function.

The manual adjustment device 16 is configured to receive the gas path flow entered by a user, and send the gas path flow entered by the user to the gas path flow control component 11. The gas path flow control component 11 is further configured to set the gas path flow entered by a user as a current gas path flow by the regulating motor 14. Generally, the system for adjusting the gas path flow of the apparatus is provided with an apparatus display for displaying various types of operating parameters of the apparatus, such as a measured parameter of a critical dimension, and a gas path flow. However, in the case where the system for adjusting the gas path flow of the apparatus is adjusted separately, a display device 17 for separately displaying the gas path flow is arranged close to the gas path regulating valve 15. If the gas path flow falls within the preset monitoring interval, a background color of a display box of the gas path flow may be set as a green color. If the gas path flow exceeds the preset monitoring interval and approximates to a critical value of the preset range of flow, the background color of the display box of the gas path flow may be set as a yellow color. In addition, the display device 17 may be further provided with the manual adjustment device 16 to receive the gas path flow entered by a user and set the gas path flow entered by the user as the current gas path flow. For example, if an ideal gas path flow is 60L/min, and the system for adjusting the gas path flow of the apparatus eventually sets the gas path flow to be 59.94 L/min, the gas path flow is manually amended to 60 L/min, enabling the apparatus to operate in an optimal state. In the embodiment, the manual adjustment device 16 may be implemented through an “increase button” (as represented by “+” in FIG. 2) and a “decrease button” (as represented by “-” in FIG. 2) on the display device 17 shown in FIG. 2. The current gas path flow is increased or decreased successively by using the buttons above, which is complementary to the automatic adjustment manner of the system for adjusting the gas path flow of the apparatus.

Based on the same concept, a method for adjusting a gas path flow of an apparatus according to embodiments of the present disclosure is further provided. FIG. 3 is a schematic flowchart of a method for adjusting a gas path flow of an apparatus according to an embodiment of the present disclosure, and the method is applicable to a device for adjusting a gas path flow of an apparatus according to any embodiment of the present disclosure. As shown in FIG. 3, the method according to the embodiment includes the following steps.

Step S110: The process task prediction component of the apparatus collects production line information and predicts a process schedule of the apparatus based on the production line information.

Step S120: The gas path flow monitoring component monitors a gas path flow of the apparatus in real time.

Step S130: The gas path flow control component judges whether the gas path flow exceeds a preset range of flow, and when the gas path flow exceeds the preset range of flow, judges a current process status of the apparatus based on the process schedule provided by the process task prediction component of the apparatus, and issues a corresponding flow control instruction based on the process status.

In embodiments of the present disclosure, the system for adjusting a gas path flow of an apparatus includes a process task prediction component of the apparatus, a gas path flow monitoring component, and a gas path flow control component, to realize an automatic adjustment of a gas path flow of an apparatus. Specifically, the process task prediction component of the apparatus predicts a process schedule of the apparatus based on collected production line information; the gas path flow monitoring component is capable of monitoring a gas path flow of the apparatus in real time; the gas path flow control component has a preset range of flow, and when the gas path flow exceeds the preset range of flow, the gas path flow control component can judge a current process status of the apparatus based on the process schedule, namely judging whether the apparatus is currently in a process trip, and issue a corresponding flow control instruction based on the process status, such that the gas path flow is adjusted to be within the preset range of flow by the gas path flow control component besides the process trip. Therefore, the gas path flow is automatically adjusted without affecting a normal process progress. The adjustment procedure is simple, and there is no need to repeatedly step down from the apparatus to adjust the gas path flow, reducing manpower burden. The procedure of adjusting the gas path flow according to the embodiments of the present disclosure would not delay each process trip, and instead, improves a working efficiency of measurement of the apparatus and accelerates product manufacturing progress.

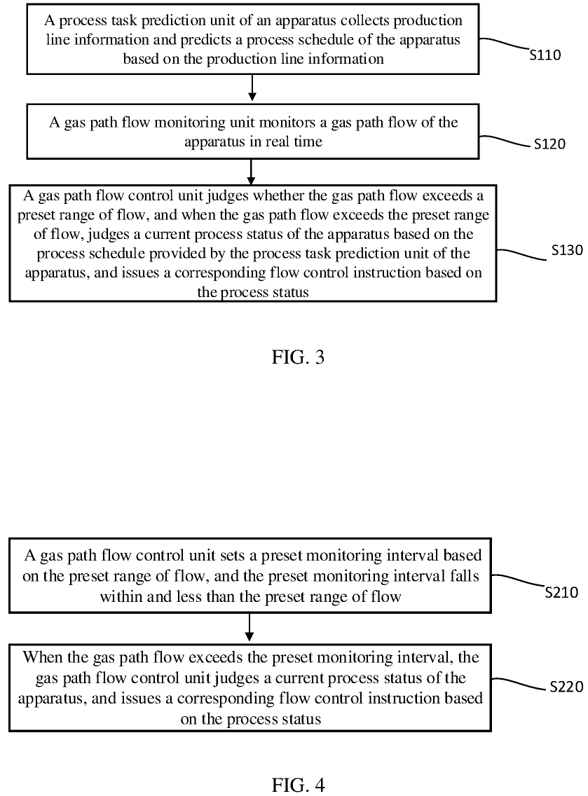

On the basis of limiting the gas path flow to within the preset range of flow according to the embodiments above, in order to prevent the gas path flow from approximating to boundary values of the preset range of flow for a long time and thus, affect critical dimension measurement results of the apparatus, a schematic flowchart of another method for adjusting a gas path flow of an apparatus according to an embodiment of the present disclosure is illustrated in FIG. 4. As show in FIG. 4, the method for adjusting the gas path flow of the apparatus according to the embodiment of the present disclosure further includes the following steps.

Step S210: The gas path flow control component sets a preset monitoring interval based on the preset range of flow, and the preset monitoring interval falls within and less than the preset range of flow.

Step S220: When the gas path flow exceeds the preset monitoring interval, the gas path flow control component judges a current process status of the apparatus, and issues a corresponding flow control instruction based on the process status.

In the present embodiment, a preset monitoring interval is set for the gas path flow. The range of the preset monitoring interval is less than the preset range of flow, so as to effectively prevent the gas path flow from approximating to the boundary values of the preset range of flow and further, limit the gas path flow to a range within the preset range of flow without approximating to the boundary values. This avoids affecting the critical dimension measurement results of the apparatus due to the pressure of the apparatus approximate to the boundary values for a long time, improves the measurement accuracy, accelerates the measurement progress, and lengthens life time of the apparatus.

Based on the embodiments described above, a median of the preset monitoring interval is the same as a median N of the preset range of flow; the preset monitoring interval is (N-0.5) to (N+0.5) L/min.

In the embodiment, in order to further limit the gas path flow to a numerical range in which a good measurement effect is realized, i.e., close to the median N of the preset range of flow. The median N is an ideal value for the gas path flow, and a small interval (N-0.5) to (N+0.5) L/min approximate to the median N is set as a median interval to further improve the measurement accuracy of the apparatus.

When the gas path flow exceeds the preset range of flow, the gas path flow control component judges a current process status of the apparatus based on the process schedule provided by the process task prediction component of the apparatus and issues a corresponding flow control instruction based on the process status, including: when the gas path flow exceeds the preset range of flow, calculating, by the gas path flow control component 11, a time interval between a current time and a next process time based on the process schedule, and judging, by the gas path flow control component, whether the apparatus is currently in an idle condition or an in-process condition; if the apparatus is in an idle condition and the time interval is no less than a preset duration, controlling the gas path flow; if the apparatus is in the in-process condition and the time interval is no less than the preset duration, controlling the gas path flow when this process trip ends; if the time interval is less than the preset duration, performing no gas path flow control this time and the apparatus continuing to operate based on the process schedule; when a next process trip is finished, repeating, by the gas path flow control component, the process above until the time interval is no less than the preset duration, and then controlling, by the gas path flow control component, the gas path flow.

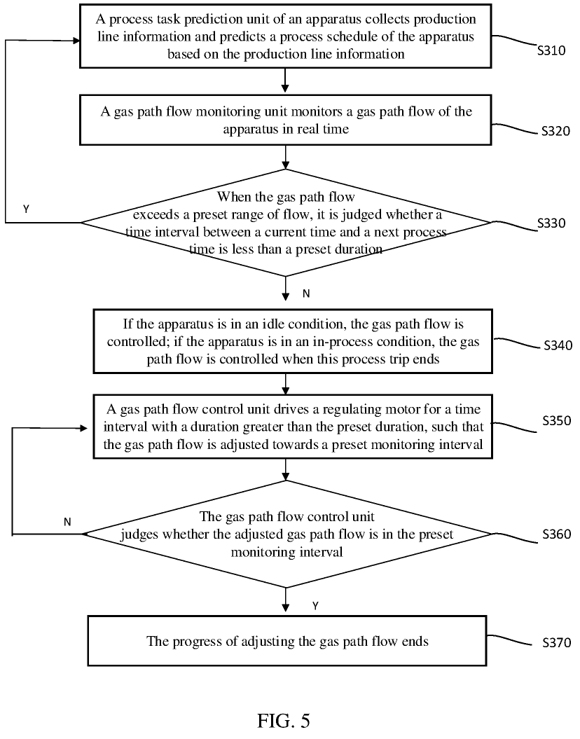

The solution of the embodiment is described in detail below by using an example, as show in the FIG. 5. FIG. 5 is a schematic flowchart of yet another method for adjusting a gas path flow of an apparatus according to an embodiment of the present disclosure. The method for adjusting the gas path flow of the apparatus according to the example further includes the following steps.

Step S310: A process task prediction component of the apparatus collects production line information and predicts a process schedule of the apparatus based on the production line information.

Step S320: A gas path flow monitoring component monitors a gas path flow of the apparatus in real time.

Step S330: If the gas path flow exceeds a preset range of flow, it is judged whether a time interval between a current time and a next process time is less than a preset duration; if no, the method proceeds to step S340, and if yes, returning to perform step S330.

Step S340: If the apparatus is in an idle condition, the gas path flow is controlled; if the apparatus is in an in-process condition, the gas path flow is controlled when this process trip ends.

Step S350: A gas path flow control component drives a regulating motor for a time interval with a duration greater than the preset duration, such that the gas path flow is adjusted towards a preset monitoring interval.

A median of the preset monitoring interval is the same as a median N of the preset range of flow; a media interval is (N-0.5) to (N+0.5) L/min.

Step S360: The gas path flow control component judges whether the adjusted gas path flow is in the preset monitoring interval; if yes, the method proceeds to step S370, and if no, returning to step S350.

Step S370: The progress of adjusting the gas path flow ends.

The embodiment is directed to limiting the gas path flow to be within the preset monitoring interval within the preset range of flow, so as to improve the measurement accuracy of the apparatus, and realize convenient and accurate adjustment of a gas path flow of an apparatus since the gas path flow is adjusted once approaching the boundary values of the preset range of flow.

It should be noted that the contents described above are merely preferred embodiments and adopted technical principles. The skills in the art can understand that the present disclosure is not limited to the particular embodiments described herein. A variety of obvious variations, readjustments, and alternatives may be made by the skills in the art without departing from the protection scope of the present disclosure. Therefore, although the present disclosure is described in greater detail by using the embodiments above, the present disclosure is not limited to only the above embodiments, and may further include many other equivalent embodiments without departing from the concepts of the present disclosure. It is intended that the scope of the present disclosure is defined by the scope of the appended claims.

What is claimed is:

1. A system for adjusting a gas path flow of an apparatus, comprising: a process task prediction component of the apparatus, a gas path flow monitoring component, and a gas path flow control component;
the process task prediction component of the apparatus is configured to collect production line information and predict a process schedule of the apparatus based on the production line information;
the gas path flow monitoring component is configured to monitor a gas path flow of the apparatus in real time; and
the gas path flow control component is communicably connected to both the process task prediction component of the apparatus and the gas path flow monitoring component, and the gas path flow control component is configured to judge whether the gas path flow exceeds a preset range of flow; when the gas path flow exceeds the preset range of flow, the gas path flow control component judges a current process status of the apparatus based on the process schedule provided by the process task prediction component of the apparatus, and issues a corresponding flow control instruction based on the process status.

2. The system for adjusting the gas path flow of the apparatus according to claim 1, wherein the process that the gas path flow control component judges a current process status of the apparatus based on the process schedule provided by the process task prediction component of the apparatus and issues a corresponding flow control instruction based on the process status comprises:
when the gas path flow exceeds the preset range of flow, calculating, by the gas path flow control component, a time interval between a current time and a next process time based on the process schedule, and judging, by the gas path flow control component, whether the apparatus is currently in an idle condition or an in-process condition; if the apparatus is in an idle condition and the time interval is no less than a preset duration, controlling the gas path flow; if the apparatus is in the in-process condition and the time interval is no less than the preset duration, controlling the gas path flow when this process trip ends;
if the time interval is less than the preset duration, performing no gas path flow control this time and the apparatus continuing to operate based on the process schedule; when a next process trip is finished, repeating, by the gas path flow control component, the process above until the time interval is no less than the preset duration, and then controlling, by the gas path flow control component, the gas path flow.

3. The system for adjusting the gas path flow of the apparatus according to claim 2, wherein the preset duration at least comprises a flow regulating duration and an apparatus stabilizing duration.

4. The system for adjusting the gas path flow of the apparatus according to claim 1, wherein the gas path flow control component is further configured to set a preset monitoring interval based on the preset range of flow, and the preset monitoring interval falls within and less than the preset range of flow; and
the gas path flow control component is further configured to judge a current process status of the apparatus when the gas path flow exceeds the preset monitoring interval, and to issue a corresponding flow control instruction based on the process status.

5. The system for adjusting the gas path flow of the apparatus according to claim 1, further comprising a display device communicably connected to the gas path flow monitoring component and configured to display the gas path flow of the apparatus in real time.

6. The system for adjusting the gas path flow of the apparatus according to claim 1, further comprising a manual adjustment device configured to receive a set gas path flow entered by a user, so as to enable the gas path flow monitoring component to issue a corresponding flow control instruction based on the set gas path flow and the process status.

7. A method for adjusting a gas path flow of an apparatus, comprising:
collecting, by a process task prediction component of the apparatus, production line information and predicting, by the process task prediction component of the apparatus, a process schedule of the apparatus based on the production line information;
monitoring, by a gas path flow monitoring component in real time, a gas path flow of the apparatus; and
judging, by a gas path flow control component, whether the gas path flow exceeds a preset range of flow, and when the gas path flow exceeds the preset range of flow, judging, by the gas path flow control component, a current process status of the apparatus based on the process schedule provided by the process task prediction component of the apparatus, and issuing, by the gas path flow control component, a corresponding flow control instruction based on the process status.

8. The method for adjusting the gas path flow of the apparatus according to claim 7, wherein when the gas path flow exceeds the preset range of flow, the gas path flow control component judges a current process status of the apparatus based on the process schedule provided by the process task prediction component of the apparatus and issues a corresponding flow control instruction based on the process status, comprising:
when the gas path flow exceeds the preset range of flow, calculating, by the gas path flow control component, a time interval between a current time and a next process time based on the process schedule, and judging, by the gas path flow control component, whether the apparatus is currently in an idle condition or an in-process condition; if the apparatus is in an idle condition and the time interval is no less than a preset duration, controlling the gas path flow; if the apparatus is in the in-process condition and the time interval is no less than the preset duration, controlling the gas path flow when this process trip ends; and
if the time interval is less than the preset duration, performing no gas path flow control this time and the apparatus continuing to operate based on the process schedule; when a next process trip is finished, repeating, by the gas path flow control component, the process above until the time interval is no less than the preset duration, and then controlling, by the gas path flow control component, the gas path flow.

9. The method for adjusting the gas path flow of the apparatus according to claim 7, further comprising:
setting, by the gas path flow control component, a preset monitoring interval based on the preset range of flow, wherein the preset monitoring interval falls within and less than the preset range of flow; and
when the gas path flow exceeds the preset monitoring interval, judging a current process status of the apparatus, and issuing a corresponding flow control instruction based on the process status.

10. The method for adjusting the gas path flow of the apparatus according to claim 7, further comprising:
the gas path flow control component receiving a set gas path flow entered by a user; and
issuing a corresponding flow control instruction based on the set gas path flow and the process status.
